(19) United States
(12) Patent Application Publication
(10) Pub. No.: US 2026/0299070 A1
(43) Pub. Date: Oct. 1, 2026

(54) Recording of Magnetic Resonance Data

(71) Applicant: Siemens Healthineers AG, Forchheim (DE)

(72) Inventor: Nicolas Groß-Weege, Nürnberg (DE)

(73) Assignee: Siemens Healthineers AG, Forchheim (DE)

(21) Appl. No.: 19/634,388

(22) Filed: Mar. 31, 2026

(30) Foreign Application Priority Data
Mar. 31, 2025 (DE) 10 2025 112 477.9

(51) Int. Cl. G01R 33/54; G01R 33/48; G01R 33/56

(52) U.S. Cl. CPC G01R 33/543; G01R 33/4828; G01R 33/5607

(57) ABSTRACT

A method is described for recording measurement data of an examination object including spin species with different chemical shifts using an VERSE RF pulse. The method may include receiving information regarding the spin species of the object from which their resonance frequencies can be determined, and adjusting the VERSE RF pulse to be applied. The adjustment may include setting a center frequency of the VERSE RF pulse to lie between a first resonance frequency of a first spin species and a second resonance frequency of a second spin species. Measurement data is then recorded using the adjusted VERSE RF pulse. By adjusting the center frequency in this manner, a layer excitation profile achieved with the VERSE RF pulse is less heavily distorted for the otherwise off-resonant spin species, enabling further reduction of the layer selection gradient magnitude without degrading achievable image quality.

### CROSS REFERENCE TO RELATED APPLICATIONS

This patent application claims priority to, and the benefit of, German Patent Application No. 10 2025 112 477.9, filed Mar. 31, 2025, which is incorporated herein by reference in its entirety.

### BACKGROUND

The disclosure relates to improved recording of magnetic resonance data, which may include using a Variable-rate Selective Excitation (VERSE) technique.

Magnetic resonance technology (the abbreviation MR stands for magnetic resonance in the following) is a known technology with which images may be generated from the inside of an examination object. Simply put, the examination object is positioned for this purpose in a magnetic resonance device in a comparatively strong, static, homogeneous basic magnetic field, also called a B0 field, with field strengths from 0.2 tesla to 7 tesla and more, so that its nuclear spins are oriented along the basic magnetic field. To trigger nuclear spin resonances measurable as signals, radio-frequency excitation pulses (RF pulses) are radiated into the examination object, the triggered nuclear spin resonances are measured as what is known as k-space data, and, on the basis of said data, MR images are reconstructed or spectroscopy data is established. The alternating magnetic field generated by the RF excitation pulses radiated by the at least one transmitter coil is also referred to as the B1 field. For spatial encoding of the measurement data, rapidly switched magnetic gradient fields, gradients for short, are superimposed on the basic magnetic field. A scheme used that describes a temporal sequence of RF pulses to be radiated and gradients to be switched is called a pulse sequence (scheme), or sequence for short. The acquired measurement data is digitized and stored as complex numerical values in a k-space matrix. An associated MR image may be reconstructed from the k-space matrix populated by values, for example, by means of a multidimensional Fourier transform.

There are essentially two ways of generating echo signals after exciting the nuclear spins. On the one hand, the excited nuclear spins can be manipulated by activating dephasing and rephasing gradients so that the signal decays more quickly than is due to the T2* decay inherent in the measured tissue, but a so-called gradient echo (GRE) to be measured forms after a certain time, the echo time (TE), after the isodelay point of the RF excitation pulse that has been used. Such sequences are generally referred to as GRE sequences.

There are many applications of magnetic resonance tomography in which it is necessary to differentiate between tissue types.

An examination object often has more than one spin species present, which can, for example, be assigned to different tissue types. Tissue types with a different chemical shift result in a different magnetic field at the core, which leads to different resonance frequencies of the various spin species. In this context, the chemical shift indicates the deviation of the resonance frequencies of the various spin species independently of a basic magnetic field B0 that is present. The various resonance frequencies result in different phase angles of the components of the various spin species when the signal is recorded. Fat and water are the most common representatives of two different tissue types and thus of spin species in a commonly recorded MR signal, wherein other applications, for example, comprising a spin species of a silicone environment, are also possible, however. The resonance frequencies of fat and water differ by approximately 3.3 ppm (parts per million). One method of separating the signals of two different tissue types, such as fat and water, is to use the phase information in recorded MR signals.

In order to achieve spatially selective excitation or other manipulation of spins in the examination object by means of an RF pulse, for example, in the layer selection direction, so-called layer selection gradients are activated during radiation of the RF pulse that, together with a bandwidth of the radiated RF pulse, define a thickness and position of a layer in which the RF pulse manipulates spins in an examined examination object. A center frequency of the radio-frequency alternating field, also referred to as the B1 field, is thereby preferably set as a rule, particularly before each measurement after determining, for example, by means of a prescan, the resonance frequencies of the relevant spin species in the examination object, so that it lies close to the resonance frequency of the spins being manipulated, for example, in proton imaging to the resonance frequency of the spin species of protons of free water molecules. Deviations of the center frequency from the resonance frequency are referred to as off-resonance.

Layer selection gradients with constant amplitude during radiation of the associated RF pulse are typically activated for selecting a layer.

Primarily used to reduce a maximum amplitude and/or a duration of an RF pulse, a VERSE technique (VERSE: “variable-rate selective excitation”) may be used. The VERSE technique allows the B1 amplitude to be reduced in the temporal center of a VERSE RF pulse by simultaneously lowering the amplitude of a layer selection gradient activated for layer selection at the same time as the VERSE RF pulse. Thus, in the case of VERSE RF pulses, a temporally variable gradient waveform is used for layer selection and a modified envelope of the RF pulse. Such VERSE RF pulses are, for example, described in the article by Conolly S, Nishimura D G, Macoviski A, Glover G “Variable-rate selective excitation” J Magn Reson, 1988; 78:440-458.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic flowchart of a method for recording measurement data.

FIG. 2 shows a comparison of a conventional RF pulse with its associated layer selection gradient shown with its envelope and a rough schematic of a VERSE RF pulse with its associated layer selection gradient shown with its envelope.

FIG. 3 shows a comparison of exemplary layer excitation profiles achieved with RF pulses according to FIG. 2.

FIG. 4 shows an exemplary MR spectrum of two different spin species.

FIG. 5 shows a schematically represented magnetic resonance system.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

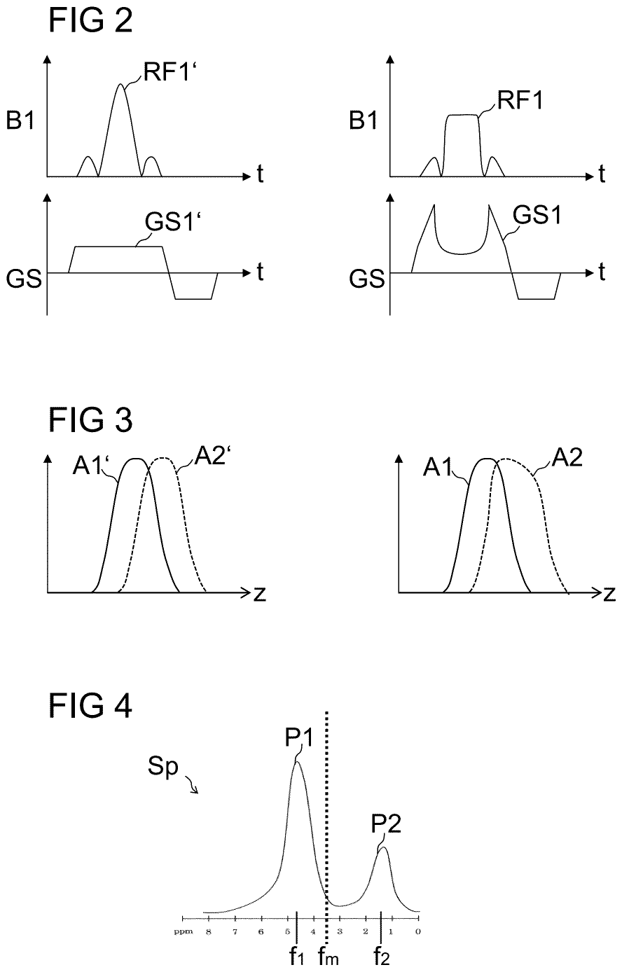

FIG. 2 shows an example RF pulse RF1′ with associated constant layer selection gradient GS1′ during the RF pulse RF1′ compared to a typical VERSE RF pulse RF1 with associated layer selection gradient GS1. The amplitude of the VERSE RF pulse RF1 is substantially reduced in its temporal center compared to the conventional RF pulse RF1′. The smaller the amplitude in the temporal center of the VERSE RF pulse RF1, the greater the reduction in the energy contribution of the VERSE RF pulse RF1, which is particularly relevant for the specific absorption rate (SAR). The magnitude of the associated layer selection gradient GS1 is likewise reduced within the temporal center of the VERSE RF pulse RF1, but has a much higher amplitude before and after this.

The reduction in the magnitude of the layer selection gradient GS1 in the temporal center of the VERSE RF pulse RF1 increases the off-resonance sensitivity of the VERSE RF pulse RF1, however. Off-resonance can be caused by inhomogeneities in the basic magnetic field B0 in the examined examination object, for example, in the vicinity of transitions between variably resonant spin species, for example, at transitions between air and water, in the vicinity of metal implants, or in the case of tissues with different dominant spin species, such as fat and water.

The greater the reduction in the amplitude of the layer selection gradient GS1, i.e., its magnitude, at the temporal center point of the associated VERSE RF pulse RF1, the greater the sensitivity of the VERSE RF pulse RF1 to off-resonance. This is particularly disadvantageous if a signal is not suppressed by fat tissue in the image and the magnitude of the layer selection gradient GS1 is reduced below a certain threshold.

FIG. 3 shows a comparison of typical layer excitation profiles A1′, A2′, A1, A2 for RF pulse RF1′ (left) and for a VERSE RF pulse RF1 (right), in each case for a first spin species with a first resonance frequency f₁ and a second spin species with a second resonance frequency f₂ that is different from the first resonance frequency f₁.

For RF pulse RF1′, the layer excitation profile A2′ of the second spin species shifts compared to the layer excitation profile A1′ of the first spin species by a distance of z₁ to z₂ in the layer selection direction z. The shift depends linearly here on the deviation of the second resonance frequency f₂ from the first resonance frequency f₁.

For a VERSE RF pulse RF1 the layer excitation profile A2 of the second spin species also shifts compared to the layer excitation profile of the first spin species in the layer selection direction z, corresponding to the deviation (from z₁ to z₂) of the second resonance frequency f₂ from the first resonance frequency f₁, but the layer excitation profile A2 of the second spin species is also distorted. The distortion is greater the smaller the amplitude of the layer selection gradient GS1 within the temporal center point of the associated VERSE RF pulse RF1. This leads to the stated VERSE RF pulses' own sensitivity to off-resonance.

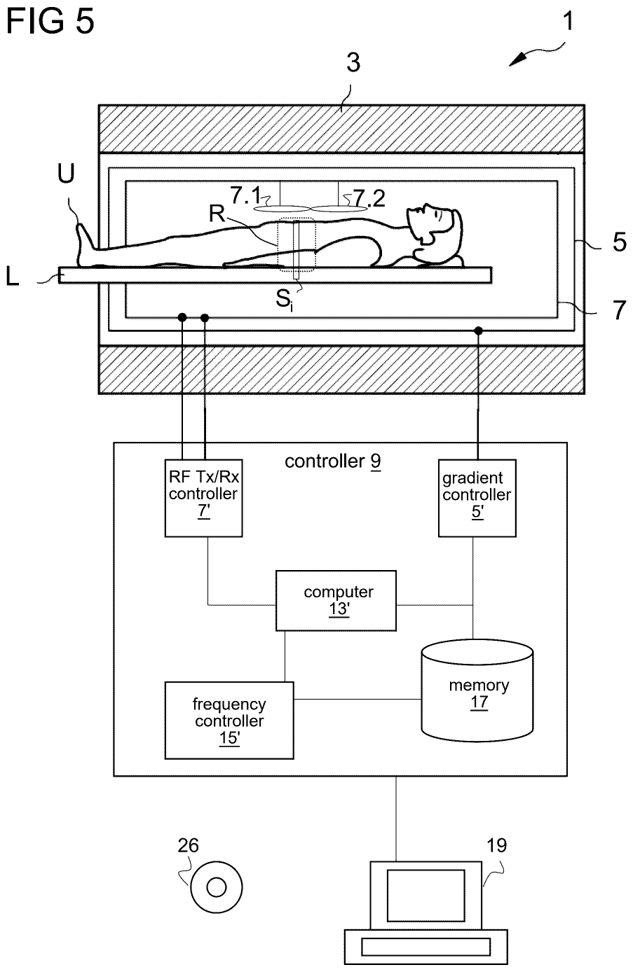

FIG. 4 shows an example spectrum Sp plotted over the chemical shift in ppm with a peak P₁ of a first spin species with a first resonance frequency f₁ (for a given basic magnetic field) and a peak P₂ of a second spin species with a resonance frequency f₂ (for the given basic magnetic field), which is different from the resonance frequency f₁.

If, for example, the center frequency fₘ of the RF pulse RF1′ or RF1 is set, as is customary, to a first resonance frequency f₁ of a first spin species, for example, water (wherein water in this instance can also be referred to as an on-resonant spin species (fₘ=f₁)), another spin species, for example, fat, nevertheless contributes to a measured signal with a resonance frequency f₂ different from the first resonance frequency f₁ according to an overlapping of the respective peaks P1, P2 of the two spin species. The more spins of a spin species present in an imaged examination region of an examined examination object, the greater the associated peaks P1, P2. For example, the more prominent a fat peak is in a spectrum, the more fat there is in the imaged examination region.

To reduce or avoid the impairment of an achievable image quality through off-resonance in MR imaging with VERSE RF pulses RF1, a threshold may be provided for the maximum amount a magnitude of the layer selection gradient GS1 can drop within the temporal center of a radiated VERSE RF pulse RF1. An example of such a restriction of a minimal amplitude of the layer selection gradient is described in DE 10 2023 206 857 A1. However, such a limit restricts the design possibilities for a VERSE RF pulse to be used so that its advantages of a reduced amplitude and thus a reduced SAR load and/or a shortened duration of the VERSE RF pulse compared to a conventional RF pulse cannot be used freely.

An object of the disclosure is to improve the creative scope in a design of VERSE RF pulses for capturing measurement data.

A method according to the disclosure for recording measurement data of an examination object, which may comprise at least two spin species with a different chemical shift, by means of a magnetic resonance system using at least one variable-rate selective excitation (VERSE) RF pulse, may comprise:
receiving information via the at least two spin species of the examination object U, from which their resonance frequencies in particular can be determined,
adjusting at least one VERSE RF pulse to be applied, wherein the adjustment may comprise adjusting a center frequency of the adjusted VERSE RF pulse in such a way that this center frequency lies between a first resonance frequency of a first spin species and a second resonance frequency of a second spin species of the spin species comprised by the examination object, and
recording measurement data using at least one adjusted VERSE RF pulse.

By means of the proposed adjustment of a center frequency of a VERSE RF pulse, so that this center frequency lies between the resonance frequencies of two different spin species (contrary to the usual placing of the center frequency as close as possible to the resonance frequency of a first of the two spin species), a layer excitation profile achieved with the VERSE RF pulse is less heavily distorted for the other (otherwise off-resonant) of the two spin species (due to the greater proximity of the center frequency to the resonance frequency of the second of the two spin species), so that it is possible to further reduce the magnitude of a layer selection gradient activated while the VERSE RF pulse is being radiated within a temporal center of the radiated VERSE RF pulse, without worsening an achievable image quality as a result, as off-resonance is thus reduced, which contributes linearly to a distortion of the layer excitation profiles. The amplitude of the VERSE RF pulse can also be reduced in this way and thus its energy contribution, for example, to the specific absorption rate, and the load it requires of an amplifier to generate the RF pulse, without the image quality suffering from this reduction.

A magnetic resonance system according to the disclosure may comprise a magnet unit, a gradient unit, a radio-frequency unit, and a controller with a frequency setting unit configured to perform a method according to the disclosure.

A computer program according to the disclosure implements a method according to the disclosure on a controller, when it is executed on the controller. For example, the computer program comprises commands that when the program is executed by a controller, for example, a controller of a magnetic resonance system, cause this controller to carry out a method according to the disclosure. The controller may be designed in the form of a computer.

The computer program may also be present in the form of a computer program product, which can be loaded directly into a memory of a controller, with program code means for executing a method according to the disclosure, when the computer program product is executed in a computing unit of a computing system of the controller.

A computer-readable storage medium according to the disclosure comprises commands that when executed by a controller, for example, a controller of a magnetic resonance system, cause this to carry out a method according to the disclosure.

The computer-readable storage medium may be designed as an electronically readable data carrier, which comprises electronically readable control information stored thereon, which comprises at least a computer program according to the disclosure and is designed such that when the data carrier is used in a controller of a magnetic resonance system it carries out a method according to the disclosure.

The advantages and statements concerning the method also apply analogously to the magnetic resonance system, the computer program product, and the electronically readable data carrier.

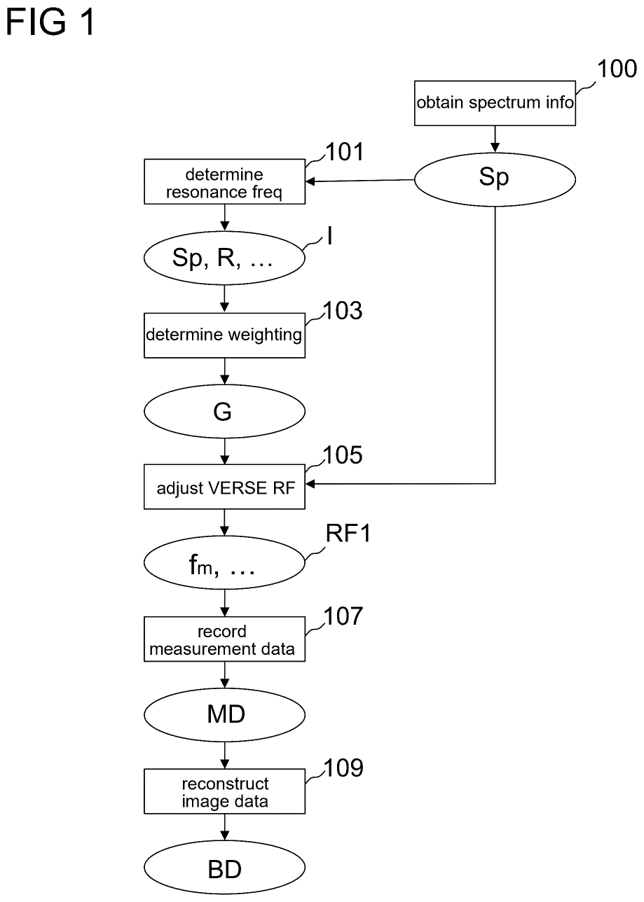

FIG. 1 is a schematic flow chart of a method according to the disclosure for recording measurement data of an examination object U, which may comprise at least two spin species with a different chemical shift, by means of a magnetic resonance system 1 using at least one variable-rate selective excitation (VERSE) RF pulse.

Information I is thereby received via the at least two spin species of the examination object U, from which their resonance frequencies can be determined (block 101). The respective resonance frequencies can, for example, be loaded from a database for a magnitude of a basic magnetic field of a magnetic resonance system that is being used, or be determined from known values of the chemical shift of the spin species and knowledge of a magnitude of a basic magnetic field of a magnetic resonance system that is being used, or be determined by means of a prescan.

The information can also comprise a measurement protocol, which can comprise in particular a desired sequence for recording measurement data MD, within which the at least one VERSE RF pulse is to be applied and radiated, with associated measurement parameters, for example, echo time, repetition time, etc., and a desired resolution, a desired contrast, and/or a purpose for recording measurement data MD. In this instance, the center frequency fₘ can also be adjusted depending on the measurement protocol to be applied. This can be useful, for example, if the measurement protocol provides for a suppression, for example, of the second spin species, for example, fat, and the center frequency fₘ can therefore be chosen to be adjusted as described below to a lesser extent.

At least one VERSE RF pulse to be applied while recording measurement data MD is adjusted (block 105), wherein the adjustment may comprise adjusting a center frequency fₘ of the adjusted VERSE RF pulse RF1 in such a way that this center frequency fₘ lies between a first resonance frequency f₁ of a first spin species and a second resonance frequency f₂ of a second spin species of the spin species comprised by the examination object U. When recording measurement data MD, consideration is given in particular to spin species of the examination object U that contribute to signals and are therefore relevant for recording measurement data MD, such as the spin species water and fat in particular.

Such a center frequency fₘ is illustrated in FIG. 4 purely as an example.

The center frequency fₘ of RF pulses, including of VERSE RF pulses, is generally set as precisely as possible to a resonance frequency of a, for example, dominant spin species or one that is to be imaged. By adjusting the center frequency fₘ of adjusted VERSE RF pulses as described and thus shifting towards a resonance frequency of an otherwise off-resonant second spin species, a distortion of a layer excitation profile A2 caused by the off-resonant excitation can be reduced by spins of the second spin species.

The center frequency fₘ of adjusted VERSE RF pulses can be adjusted in a simple embodiment in such a way that the center frequency fₘ of adjusted VERSE RF pulses lies centrally between the first resonance frequency f₁ and the second resonance frequency f₂. This requires less computational effort and can also improve image quality.

Received information I can comprise a desired examination region R of the examination object U, for which measurement data MD is to be recorded. Thus, the center frequency fₘ of adjusted VERSE RF pulses can be adjusted depending on the examination region R, which can, for example, be a body region or a patient as the examination object U. Adjusting the center frequency fₘ, particularly for examination regions R, in which the second spin species with the second resonance frequency f₂ is known to be more represented, can result in the center frequency fₘ being shifted closer to the second resonance frequency f₂ than is the case for examination regions R, in which the second spin species with the second resonance frequency f₂ is known to be represented less heavily. The value by which the center frequency fₘ, for example, away from the first resonance frequency f₁ and towards the second resonance frequency f₂, for example, according to a stored table that assigns corresponding preselected shift values to the typical occurrence of the second spin species, can be selected automatically and applied when adjusting the center frequency fₘ.

Additionally or alternatively, the received information can also comprise a spectrum Sp comprising peaks at least for the first and the second spin species. The spectrum Sp can be loaded here again as a typical spectrum Sp of the at least two spin species from a database, particularly depending on a desired examination region R (block 100).

It is also conceivable to load such a spectrum Sp as a spectrum measured by means of a prescan (block 100).

The center frequency fₘ can then be adjusted depending on a spectrum Sp comprised by the received information.

In particular, a weighting G can be determined (block 103) depending on such a spectrum Sp, which indicates the point at which the center frequency fₘ of the adjusted VERSE RF pulse is located between the first resonance frequency f₁ and the second resonance frequency f₂.

The weighting can, for example, be determined on the basis of a variable for at least one of the peaks P1, P2 of the spectrum Sp, wherein a variable of a peak P1, P2 can be in particular its maximum amplitude and/or an integral over the peak P1, P2.

Such a weighting G can, for example, be effected in each case depending on the maximum amplitudes of at least one peak P1, P2 in the spectrum Sp. It is conceivable in particular here for the weighting G to be derived only from the maximum amplitude of the peak P2 of the second spin species. It is also conceivable for the weighting G to be derived from a mean or a median of the maximum amplitudes of both peaks P1, P2 of the spectrum Sp, so that the closer the adjustment of the center frequency fₘ of adjusted VERSE RF pulses to the second resonance frequency f₂, the greater the contribution of the second spin species to the signal.

Such a weighting G can, for example, also be effected depending on an integral over at least one of the peaks P1, P2 in the spectrum Sp. It is conceivable in particular here for the weighting G to be derived only from an integral over the peak P2 of the second spin species. It is also conceivable for the weighting G to be derived from a mean or a median of the integrals over each of the two peaks P1, P2 of the spectrum Sp, so that the closer the adjustment of the center frequency fₘ of adjusted VERSE RF pulses to the second resonance frequency f₂, the greater the contribution of the second spin species to the signal.

A degree of shifting of the center frequency fₘ while adjusting the adjusted VERSE RF pulses, for example, away from the first resonance frequency f₁, for example, the resonance frequency of water, towards a second resonance frequency f₂, for example, the resonance frequency of fat, can thus be selected (automatically) according to the desired measurement protocol, the desired examination region R, and/or a present spectrum Sp corresponding to the present individual case, in order to improve the image quality individually.

Measurement data MD is recorded (block 107) using at least one adjusted VERSE RF pulse, for example, according to the desired measurement protocol, from which image data BD can be reconstructed (block 109).

FIG. 5 is a schematic representation of a magnetic resonance system 1 according to the disclosure. This may comprise a magnet unit 3 for generating a basic magnetic field, a gradient unit 5 for generating the gradient fields, a radio-frequency unit 7 for radiating and receiving radio-frequency signals, and a controller 9 configured to carry out a method according to the disclosure.

The schematic in FIG. 5 is a rough representation of these subunits of the magnetic resonance system 1. The radio-frequency unit 7 may comprise a plurality of subunits and, for example, multiple coils. In particular, the radio-frequency unit 7 may comprise a body coil that is permanently integrated into the magnetic resonance system 1 and in turn may, for example, comprise two antenna elements 7.1 and 7.2. The radio-frequency unit 7 may also comprise one or more different local coils, which can be configured to only send radio-frequency signals, only receive the triggered radio-frequency signals, or for both, and may themselves comprise multiple antenna elements and associated coil channels.

To examine an examination object U, for example, a patient or also a phantom, this may be introduced on a bed L into the magnetic resonance system 1 in its measurement volume. The layer Sᵢ represents an exemplary target volume for recording measurement data in an examination region R of the examination object U, from which echo signals may be recorded and acquired as measurement data.

The controller 9 may be configured to control the magnetic resonance system 1, which may include to control the gradient unit 5 by gradient controller 5′ and the radio-frequency (RF) unit 7 by a radio-frequency (RF) transmit/receive (Tx/Rx) controller 7′. The radio-frequency unit 7 may comprise a plurality of channels, on which signals may be sent or received. The controller 9 may include processing circuitry configured to perform one or more functions and/or operations of the controller 9. Additionally, or alternatively, one or more components of the controller 9 may include processing circuitry that is configured to perform one or more respective functions of the component(s).

The radio-frequency unit 7, together with its radio-frequency transmit/receive controller 7′, is responsible for generating and radiating (transmitting) a radio-frequency alternating field for manipulation of the spins in an area to be manipulated (for example, in layers to be measured S) of the examination object U. The center frequency of the radio-frequency alternating field, also referred to as the B1 field, is thereby set in the manner proposed herein in such a way that it lies between the resonance frequencies of two relevant spin species. To generate the B1 field, in the radio-frequency unit 7 currents controlled by means of the radio-frequency transmit/receive controller 7′ are applied to the HF coils.

The controller (control facility) 9 may also comprise a frequency setting unit (frequency controller) 15 configured to determine/set the center frequency of the radiated RF pulses. The controller 9 may be configured to control the operation of the system, which may include carrying out a method according to the disclosure.

A computing unit (computer, processor) 13 included in the controller 9 may be configured to carry out all calculation operations required for the necessary measurements and determinations. Intermediate results and results necessary for or determined in the course of this may be stored in a memory storage unit (memory) 17 of the controller 9. The units shown should not necessarily be understood to be physically separate units, but merely represent a subdivision into meaningful units that may, for example, also be implemented in fewer of these or also in just a single physical unit, however.

Through an input/output (I/O) facility (also referred to as I/O interface) 19 of the magnetic resonance system 1, for example, by a user, control commands may be directed to the magnetic resonance system and/or results such as image data may be displayed from the controller 9.

A method described herein may also be present in the form of a computer program, comprising commands that carry out the method described on a controller 9. A computer-readable storage medium may also be present, comprising commands that when executed by a controller 9 of a magnetic resonance system 1 cause this to carry out the method described.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for recording measurement data of an examination object, which comprises at least two spin species with a different chemical shift, by means of a magnetic resonance system using at least one variable-rate selective excitation (VERSE) radio-frequency pulse, the method comprising:
receiving information via the at least two spin species of the examination object, the information being associated with the respective resonance frequencies of the at least two spin species;
adjusting at least one VERSE RF pulse to be applied, the adjustment comprising adjusting a center frequency of the adjusted VERSE RF pulse such that the center frequency of the adjusted VERSE RF pulse lies between a first resonance frequency of a first spin species and a second resonance frequency of a second spin species of the spin species comprised by the examination object; and
recording measurement data using the at least one adjusted VERSE RF pulse.

2. The method as claimed in claim 1, wherein the adjustment of the center frequency of the at least one adjusted VERSE RF pulse places adjusted center frequency in a center between the first resonance frequency and the second resonance frequency.

3. The method as claimed in claim 1, wherein the received information comprises an examined region of the examination object, for which the measurement data is to be recorded, and the center frequency is adjusted based on the examination region.

4. The method as claimed in claim 1, wherein the received information comprises a spectrum, and the center frequency is adjusted based on the spectrum.

5. The method as claimed in claim 4, wherein, based on the spectrum, a weighting is determined associated with a point at which the adjusted center frequency is located between the first resonance frequency and the second resonance frequency.

6. The method as claimed in claim 5, wherein the weighting takes place based on maximum amplitudes of peaks in the spectrum in each instance.

7. The method as claimed in claim 5, wherein the weighting is based on integrals over peaks occurring in the spectrum.

8. The method as claimed in claim 5, wherein the weighting is determined based on a mean or a median of a variable of the spectrum.

9. The method as claimed in claim 8, wherein the variable comprises a maximum amplitude of one or more peaks of the spectrum and/or an integral over the one of the peaks of the spectrum.

10. The method as claimed in claim 4, wherein the received information comprises an examination region of the examination object and the spectrum is a typical spectrum for the examination region loaded from a database.

11. The method as claimed in claim 4, wherein the spectrum is a spectrum measured by a prescan.

12. The method as claimed in claim 1, wherein the adjustment further comprises reducing a magnitude of an activated layer selection gradient associated with radiation of the adjusted VERSE RF pulse within a temporal center of the radiated VERSE RF pulse.

13. The method as claimed in claim 1, wherein the first spin species is water and the second spin species is fat.

14. One or more non-transitory media storing instructions that, when executed by one or more processors, cause the one or more processors to perform the method of claim 1.

15. A magnetic resonance (MR) system, comprising:
a scanner; and
a controller configured to interface with the scanner to perform the method of claim 1.

16. The MR system as claimed in claim 15, wherein the scanner comprises a magnet unit, a gradient unit, and a radio-frequency unit.

17. An apparatus comprising:
one or more processors; and
memory storing instructions that, when executed by the one or more processors, cause the apparatus to perform the method of claim 1.
